(19) United States
(12) Patent Application Publication
(10) Pub. No.: US 2013/0093073 A1
(43) Pub. Date: Apr. 18, 2013

(54) HIGH THERMAL PERFORMANCE 3D PACKAGE ON PACKAGE STRUCTURE

(71) Applicants: Tai-Yu CHEN, Taipei City (TW); Chun-Wei CHANG, New Taipei City (TW); Chung-Hwa WU, Tainan City (TW)

(72) Inventors: Tai-Yu CHEN, Taipei City (TW); Chun-Wei CHANG, New Taipei City (TW); Chung-Hwa WU, Tainan City (TW)

(73) Assignee: MEDIATEK INC., Hsin-Chu (TW)

(21) Appl. No.: 13/612,737

(22) Filed: Sep. 12, 2012

Related U.S. Application Data
(60) Provisional application No. 61/548,092, filed on Oct. 17, 2011.

(51) Int. Cl. H01L 23/34

(52) U.S. Cl. 257/686; 257/E23.08

(57) ABSTRACT

A package on package (PoP) structure is disclosed. The PoP structure includes a top package and a bottom package disposed thereunder. The top package includes a first substrate and a first die mounted onto the first substrate. The first substrate has a thermal conductivity which is more than 70 W/(m×K). The bottom package includes a second substrate and a second die mounted onto the second substrate. An upper surface of the second die is in thermal contact with a lower surface of the first substrate.

### CROSS REFERENCE TO RELATED APPLICATIONS

This application claims the benefit of U.S. Provisional Application No. 61/548,092, filed Oct. 17, 2011, the entirety of which is incorporated by reference herein.

### BACKGROUND OF THE INVENTION

1. Field of the Invention

The invention relates to semiconductor package technology, and more particularly to a three dimensional (3D) package on package (PoP) structure.

2. Description of the Related Art

With the development of the electronic industries, such as industries related to the 3Cs (Computer, Communications and Consumer electronics), there have been rapidly increasing demands for multi-functional, more convenient and smaller devices. These demands have further driven the need for increased integrated circuit (IC) density. This increased IC density has led to the development of multi-chip packages, such as a package in package (PiP) and package on package on package (PoP). With demands for high performance and high integration, the 3D PoP, which stacks a top package on a bottom package, has been accepted as an alternative choice.

PoP, a package technology, may allow the integration of different chip (also called die) functions, for chips such as microprocessors or memory, logic, or optic ICs. PoP, however, requires a much higher power density than an individual single chip (or die) package. Thus, thermal management is more and more critical as power density increases and the size of semiconductor devices in chips decreases (i.e., IC density increases). The increased power and IC density has increased the amount of heat generated from the chips in the PoP structure. Excessive amounts of heat typically decrease device performance and damage may occur in devices.

One of approaches to combat such heat includes providing a heat spreader in thermal contact with the chip. In the PoP structure, however, the presence of a top package obstructs the placement of the heat spreader between the top and bottom packages. Thus, it is difficult to dissipate the heat generated from the bottom package by the use of the heat spreader.

Accordingly, there is a need to develop a novel PoP structure which is capable of mitigating or eliminating the aforementioned problem.

### BRIEF SUMMARY OF THE INVENTION

An exemplary embodiment of a package on package (PoP) structure comprises a top package and a bottom package disposed thereunder. The top package comprises a first substrate and a first die mounted onto the first substrate. The first substrate has a thermal conductivity which is more than 70 W/(m×K). The bottom package comprises a second substrate and a second die mounted onto the second substrate. An upper surface of the second die is in thermal contact with a lower surface of the first substrate.

Another exemplary embodiment of a PoP structure comprises a top package and a bottom package disposed thereunder. The top package comprises a first substrate and a first die mounted onto the first substrate. At least one electrically floating pad is disposed on a lower surface of the first substrate. The bottom package comprises a second substrate and a second die mounted onto the second substrate. An upper surface of the second die is in thermal contact with the electrically floating pad.

### BRIEF DESCRIPTION OF DRAWINGS

The invention can be more fully understood by reading the subsequent detailed description and examples with references made to the accompanying drawings, wherein:

FIGS. 1-9 are cross sections of various exemplary embodiments of a package on package structure according to the invention.

### DETAILED DESCRIPTION OF INVENTION

The following description encompasses a fabrication process and purpose of the invention. It can be understood that this description is provided for the purpose of illustrating the fabrication process and the use of the invention and should not be taken in a limited sense. In the drawings or disclosure, the same or similar elements are represented or labeled by the same or similar symbols. Moreover, the shapes or thicknesses of the elements shown in the drawings may be magnified for simplicity and convenience. Additionally, the elements not shown or described in the drawings or disclosure are common elements which are well known in the art.

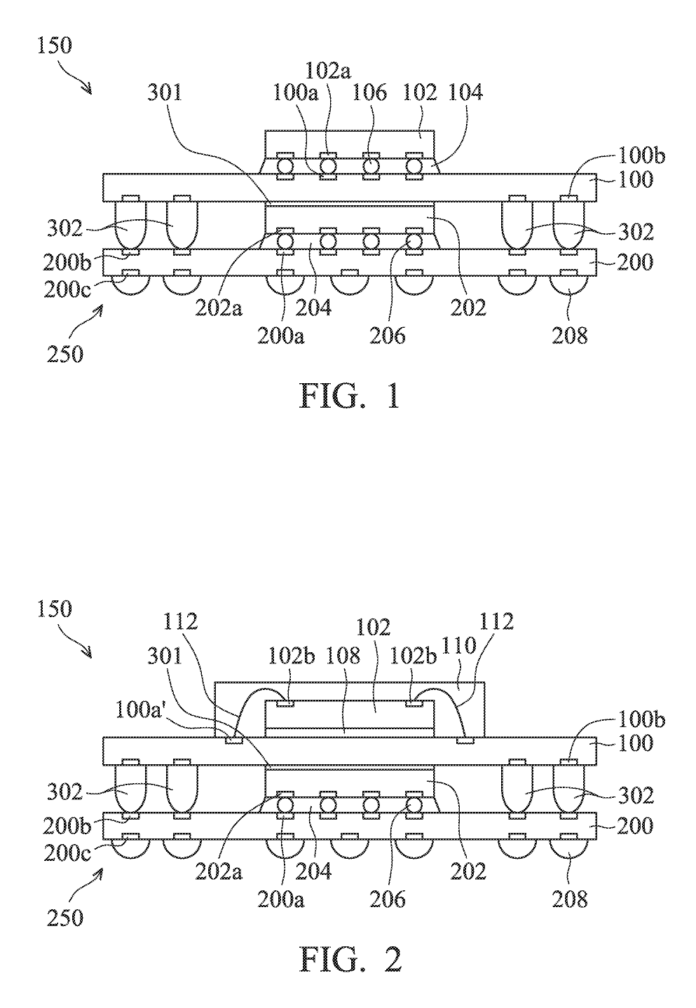

Referring to FIG. 1, which is a cross section of an exemplary embodiment of a package on package (PoP) structure according to the invention. In the embodiment, the PoP structure comprises a top package 150 and a bottom package 250 disposed under the top package 150. The top package 150 comprises a first substrate 100 and a first die 102 mounted onto the first substrate 100. The first substrate 100 serves as a package substrate. Particularly, the first substrate 100 also serves as a heat dissipation plate for the bottom package 250. In the embodiment, the first substrate 100 has a thermal conductivity which is more than 70 W/(m×K) and may comprise a silicon substrate. Pluralities of contact/bond pads 100a and 100b are formed on upper and lower surfaces of the first substrate 100, respectively. The pluralities of contact/bond pads 100a and 100b are used for electrical connection between the first die 102 and the bottom package 250. The first die 102, such as a memory die, may comprise a plurality of contact/bond pads 102a formed on the lower surface thereof The first die 102 may be mounted onto the first substrate 100 by conventional flip chip method. For example, the first die 102 is electrically connected to the first substrate 100 by a plurality of bumps 106 between the bond pads 100a and 102a. An underfill material 104, such as epoxy, is filled into the space between the first substrate 100 and the first die 102 to protect the plurality of bumps 106.

The bottom package 250 comprises a second substrate 200 and a second die 202 mounted onto the second substrate 200. In one embodiment, the second substrate 200 may serve as a package substrate. For example, the second substrate 200 may comprise a ceramic substrate or a printed circuit board (PCB). In another embodiment, the second substrate 200 may comprise a substrate which is the same as that of the first substrate 100. Namely, the second substrate 200 also has a thermal conductivity which is more than 70 W/(m×K) and may comprise a silicon substrate. Pluralities of contact/bond pads 200a and 200b are formed on an upper surface of the second substrate 200. Moreover, a plurality of contact/bond pads 200c formed on a lower surface of the second substrate 200. The pluralities of contact/bond pads 200a and 200b are used for electrical connection between the second die 202 and the top package 150. The plurality of contact/bond pads 200c is connected to a plurality of bumps 208, thereby electrical connecting the PoP structure to exterior circuits (not shown). The second die 202 may be a high power die, such as a microprocessor die. Also, the second die 202 may comprise a plurality of contact/bond pads 202a formed on the lower surface thereof The second die 202 may be mounded onto the first substrate 100 by conventional flip chip method. For example, the second die 202 is electrically connected to the second substrate 200 by a plurality of bumps 206 between the bond pads 200a and 202a. An underfill material 204, such as epoxy, is filled into the space between the second substrate 200 and the second die 202 to protect the plurality of bumps 206.

In the embodiment, the PoP structure further comprise a plurality of bumps 302 interposed between the bond pads 100b of the first substrate 100 and the bond pads 200b of the second substrate 200, such that the first substrate 100 and the first die 102 thereon are electrically connected to the second substrate 200 and the second die 202 thereon.

The second die 202 is a high power die and may generate a lot of heat during device operation, and thus the heat generated therefrom must be dissipated. In the embodiment, an upper surface of the second die 202 is in thermal contact with the lower surface of the first substrate 100, such that heat dissipation is accomplished by a thermal conductive path created by the first substrate 100. In one embodiment, the second die 202 may be in thermal contact with the first substrate 100 by a thermal interface material (TIM) 301 disposed therebetween. The TIM 301 may comprise solder or copper bump or thermal grease (consist of silicone oil filled with metal powder), or micronized silver or any kind of phase change material. In another embodiment, the second die 202 may be in thermal contact with the first substrate 100 by a direct contact therebetween.

Referring to FIG. 2, which is a cross section of an exemplary embodiment of a PoP structure according to the invention. Elements in FIG. 2 that are the same as those in FIG. 1 are labeled with the same reference numbers as in FIG. 1 and are not described again for brevity. In the embodiment, the first die 102 is mounted onto the first substrate 100 by a wire bonding process. For example, the bottom surface of the first die 102 is attached onto the upper surface of the first substrate 100 by an adhesion layer 108. Moreover, a plurality of wires 112 electrical connects a plurality of contact/bond pads 102b of the first die 102 to a plurality of contact/bond pads 100a′ of the first substrate 100. In the embodiment, the first die 102 and the plurality of wires 112 are covered by an encapsulating material 102, such as epoxy.

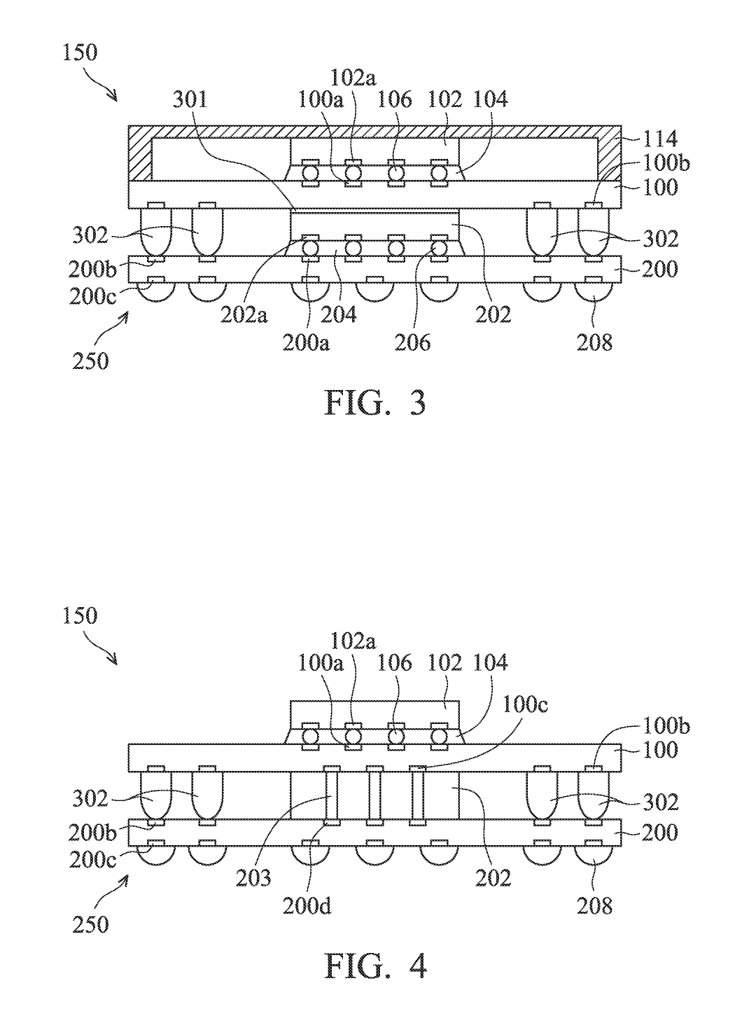

Referring to FIG. 3, which is a cross section of an exemplary embodiment of a PoP structure according to the invention. Elements in FIG. 3 that are the same as those in FIG. 1 are labeled with the same reference numbers as in FIG. 1 and are not described again for brevity. In the embodiment, the PoP structure is the same as that shown in FIG. 1 except a heat spreader is added. The top package 150 further comprises a heat spreader 114 in thermal contact with the upper surface of the first die 102. For example, the heat spreader 114 is disposed on the first substrate 100 and covers the first die 102. The heat spreader 114 may dissipate the heat generated from the first die 102. Moreover, a thermal conductive path can be created by the heat spreader 114 and the first substrate 100 to further dissipate the heat generated from the second die 202. Accordingly, the heat dissipation efficiency of the PoP structure can be further increased as compared to that shown in FIGS. 1 and 2.

Referring to FIG. 4, which is a cross section of an exemplary embodiment of a PoP structure according to the invention. Elements in FIG. 4 that are the same as those in FIG. 1 are labeled with the same reference numbers as in FIG. 1 and are not described again for brevity. In the embodiment, the PoP structure is similar as that shown in FIG. 1. Unlike the PoP structure shown in FIG. 1, the second die 202 of the bottom package 250 may comprise a plurality of through substrate vias (TSVs) 203 therein. The plurality of TSVs 203 is electrically connected to a plurality of contact/bond pads 100c of the first substrate 100 and a plurality of contact/bond pads 200d of the second substrate 200, such that the second die 202 is electrically connected to the first and second substrates 100 and 200 by the plurality of TSVs 203. In the embodiment, the second die 202 may be in thermal contact with the first substrate 100 by a thermal interface material (not shown) or by a direct contact therebetween.

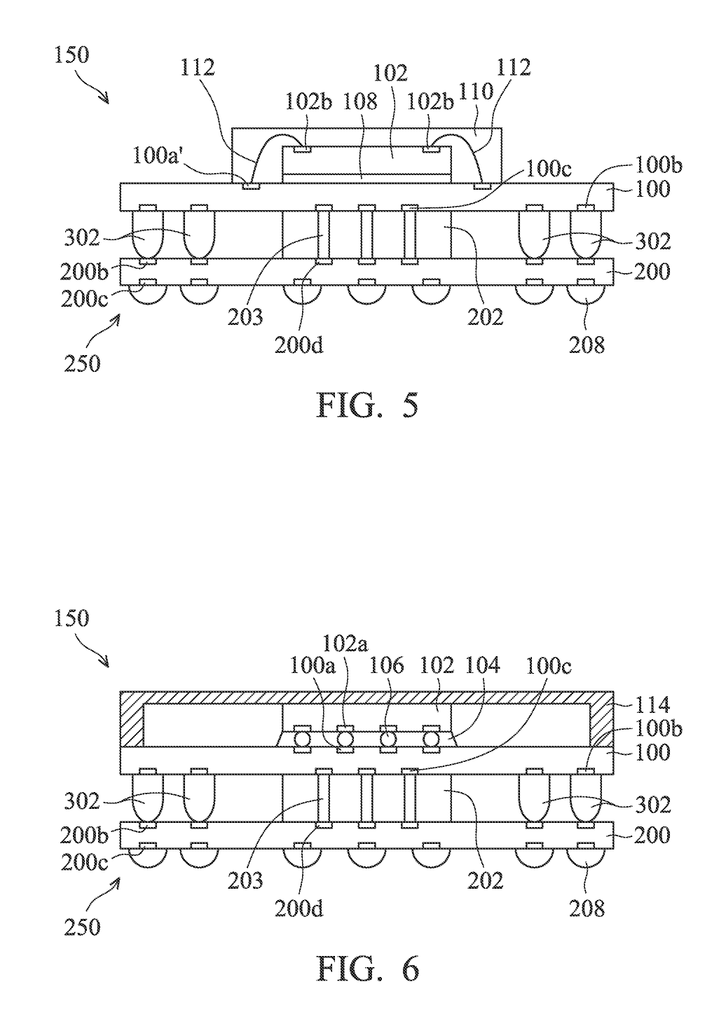

Referring to FIG. 5, which is a cross section of an exemplary embodiment of a PoP structure according to the invention. Elements in FIG. 5 that are the same as those in FIG. 2 are labeled with the same reference numbers as in FIG. 2 and are not described again for brevity. In the embodiment, the PoP structure is similar as that shown in FIG. 2. Unlike the PoP structure shown in FIG. 2, the second die 202 of the bottom package 250 may comprise a plurality of TSVs 203 therein. Moreover, the plurality of TSVs 203 is electrically connected to a plurality of contact/bond pads 100c of the first substrate 100 and a plurality of contact/bond pads 200d of the second substrate 200, such that the second die 202 is electrically connected to the first and second substrates 100 and 200. Also, the second die 202 may be in thermal contact with the first substrate 100 by a thermal interface material (not shown) or by a direct contact therebetween.

Referring to FIG. 6, which is a cross section of an exemplary embodiment of a PoP structure according to the invention. Elements in FIG. 6 that are the same as those in FIG. 3 are labeled with the same reference numbers as in FIG. 3 and are not described again for brevity. In the embodiment, the PoP structure is similar as that shown in FIG. 3. Unlike the PoP structure shown in FIG. 3, the second die 202 of the bottom package 250 may comprise a plurality of TSVs 203 therein. Moreover, the plurality of TSVs 203 is electrically connected to a plurality of contact/bond pads 100c of the first substrate 100 and a plurality of contact/bond pads 200d of the second substrate 200, such that the second die 202 is electrically connected to the first and second substrates 100 and 200. Also, the second die 202 may be in thermal contact with the first substrate 100 by a thermal interface material (not shown) or by a direct contact therebetween.

According to the foregoing embodiments, since the package substrate in the top package of the PoP structure can create a thermal conductive path, the heat generated from the bottom package of the PoP structure can be dissipated without placing any heat spreader between the top and bottom packages. Accordingly, the device performance can be prevented from being lowered and devices can be prevented from damage. Moreover, since an additional heat spreader can be disposed on the top package of the PoP structure, heat generated from the dice in the PoP structures can be further dissipated by the heat spreader, thereby increasing the heat dissipation efficiency.

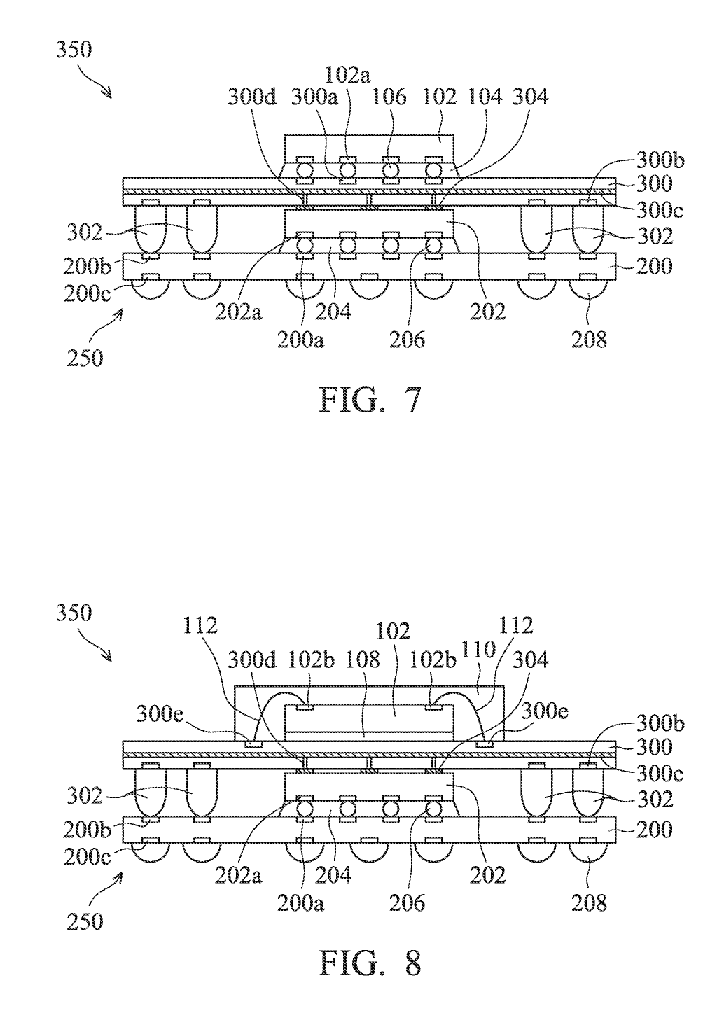

Referring to FIG. 7, which is a cross section of an exemplary embodiment of a PoP structure according to the invention. Elements in FIG. 7 that are the same as those in FIG. 1 are labeled with the same reference numbers as in FIG. 1 and are not described again for brevity. In the embodiment, the PoP structure is similar as that shown in FIG. 1. Unlike the PoP structure shown in FIG. 1, the first substrate 300 of the top package 150 may comprise a PCB and serve as a package substrate, wherein at least three copper layers are embedded in different levels of the PCB. In one embodiment, these copper layers comprise a plurality of contact/bond pads 300a, a plurality of contact/bond pads 300b, and a heat dissipation plate 300c. One or more electrically floating pads 304 are disposed on the lower surface of the first substrate 300, wherein the electrically floating pads 304 are connected to the one of the copper layers (i.e., the heat dissipation plate 300c) by vias 300d formed in the first substrate 300. Moreover, the upper surface of the second die 200 is in thermal contact with at least one electrically floating pad 304, such that heat dissipation is accomplished by a thermal conductive path created by the electrically floating pad 304, the vias 300d, and the heat dissipation plate 300c. In one embodiment, the second die 202 may be in thermal contact with the electrically floating pad 304 by a thermal interface material (not shown), such as solder or copper bump or thermal grease (consist of silicone oil filled with metal powder), or micronized silver or any kind of phase change material, disposed therebetween.

The pluralities of contact/bond pads 300a and 300b are used for electrical connection between the second die 202 and the top package 150. Also, the plurality of contact/bond pads 300a is used for electrical connection between the first die 102 and the bottom package 250. Moreover, the PoP structure further comprise a plurality of bumps 302 interposed between the bond pads 300b of the first substrate 300 and the bond pads 200b of the second substrate 200, such that the first substrate 300 and the first die 102 thereon are electrically connected to the second substrate 200 and the second die 202 thereon.

Additionally, in one embodiment, the second die 200 may comprise a plurality of TSVs (not shown) therein, as the second die 200 shown in FIGS. 4, 5, and 6, such that the second die 200 is electrically connected to the first substrate 300 by the plurality of TSVs.

Referring to FIG. 8, which is a cross section of an exemplary embodiment of a PoP structure according to the invention. Elements in FIG. 8 that are the same as those in FIGS. 2 and 7 are labeled with the same reference numbers as in FIGS. 2 and 7 and are not described again for brevity. Unlike the PoP structure shown in FIG. 2, the first substrate 300 of the top package 150 may comprise a PCB and serve as a package substrate, as the first substrate 300 shown in FIG. 7. Moreover, a plurality of wires 112 electrical connects a plurality of contact/bond pads 102b of the first die 102 to a plurality of contact/bond pads 300e of the first substrate 300. In the embodiment, the upper surface of the second die 200 is in thermal contact with at least one electrically floating pad 304, such that heat dissipation is accomplished by a thermal conductive path created by the electrically floating pad 304, the vias 300d, and the heat dissipation plate 300c.

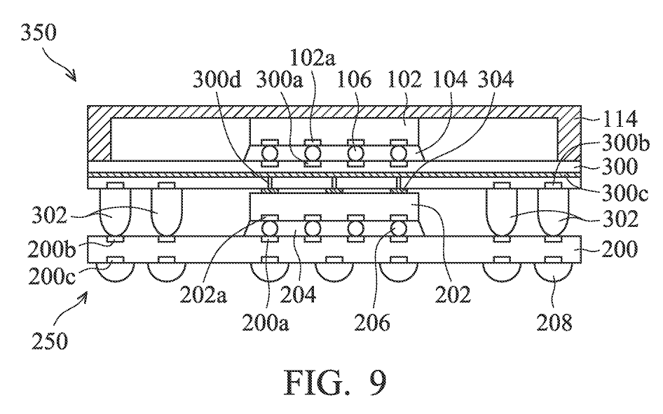

Referring to FIG. 9, which is a cross section of an exemplary embodiment of a PoP structure according to the invention. Elements in FIG. 9 that are the same as those in FIGS. 3 and 7 are labeled with the same reference numbers as in FIGS. 3 and 7 and are not described again for brevity. Unlike the PoP structure shown in FIG. 3, the first substrate 300 of the top package 150 may comprise a PCB and serve as a package substrate, as the first substrate 300 shown in FIG. 7. In the embodiment, the upper surface of the second die 200 is in thermal contact with at least one electrically floating pad 304, such that heat dissipation is accomplished by a thermal conductive path created by the electrically floating pad 304, the vias 300d, the heat dissipation plate 300c, and the heat spreader 114.

According to the foregoing embodiments, since the heat dissipation plate and the electrically floating pad in the top package of the POP structure can create a thermal conductive path, the heat generated from the bottom package of the PoP structure can be dissipated without placing any heat spreader between the top and bottom packages. Accordingly, the device performance also can be prevented from being lowered and devices can be prevented from damage. Moreover, since an additional heat spreader can be disposed on the top package of the PoP structure, heat generated from the dice in the PoP structures can be further dissipated by the heat spreader, thereby increasing the heat dissipation efficiency.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A package on package structure, comprising:
a top package comprising a first substrate and a first die mounted onto the first substrate, wherein the first substrate has a thermal conductivity which is more than 70 W/(m×K); and
a bottom package disposed under the top package, comprising a second substrate and a second die mounted onto the second substrate, wherein an upper surface of the second die is in thermal contact with a lower surface of the first substrate.

2. The package on package structure of claim 1, wherein the top package further comprises a heat spreader in thermal contact with an upper surface of the first die.

3. The package on package structure of claim 1, wherein the first die is electrically connected to the first substrate by a plurality of bumps or wires.

4. The package on package structure of claim 1, wherein the first substrate is a silicon substrate.

5. The package on package structure of claim 1, wherein the second die comprises a plurality of through substrate vias therein, such that the second die is electrically connected to the first substrate by the plurality of through substrate vias.

6. The package on package structure of claim 1, wherein the second die is in thermal contact with the first substrate by a thermal interface material disposed therebetween or by a direct contact therebetween.

7. The package on package structure of claim 6, wherein the thermal interface material comprises solder or copper bump, thermal grease, or micronized silver.

8. The package on package structure of claim 1, further comprising a plurality of bumps interposed between the first substrate and the second substrate, such that the first substrate is electrically connected to the second substrate.

9. The package on package structure of claim 1, wherein the second substrate has a thermal conductivity which is more than 70 W/(m×K).

10. The package on package structure of claim 9, wherein the second substrate is a silicon substrate.

11. A package on package structure, comprising:
a top package comprising a first substrate and a first die mounted onto the first substrate, wherein at least one electrically floating pad is disposed on a lower surface of the first substrate; and
a bottom package disposed under the top package, comprising a second substrate and a second die mounted onto the second substrate, wherein an upper surface of the second die is in thermal contact with the electrically floating pad.

12. The package on package structure of claim 11, wherein the top package further comprises a heat spreader in thermal contact with an upper surface of the first die.

13. The package on package structure of claim 11, wherein the first die is electrically connected to the first substrate by a plurality of bumps or wires.

14. The package on package structure of claim 11, wherein the first substrate is a print circuit board.

15. The package on package structure of claim 14, wherein at least three copper layers are embedded in different levels of the print circuit board, and wherein the electrically floating pad is connected to one of the copper layers.

16. The package on package structure of claim 11, wherein the second die comprises a plurality of through substrate vias therein, such that the second die is electrically connected to the first substrate by the plurality of through substrate vias.

17. The package on package structure of claim 11, wherein the second die is in thermal contact with the electrically floating pad by a thermal interface material disposed therebetween.

18. The package on package structure of claim 17, wherein the thermal interface material comprises solder or copper bump, thermal grease, or micronized silver.

19. The package on package structure of claim 11, further comprising a plurality of bumps interposed between the first substrate and the second substrate, such that the first substrate is electrically connected to the second substrate.
